(19) United States
(12) Patent Application Publication
(10) Pub. No.: US 2012/0073963 A1
(43) Pub. Date: Mar. 29, 2012

(54) SPUTTERING APPARATUS HAVING SHIELDING DEVICE

(75) Inventor: CHUNG-PEI WANG, Tu-Cheng (TW)

(73) Assignee: HON HAI PRECISION INDUSTRY CO., LTD., Tu-Cheng (TW)

(21) Appl. No.: 12/944,748

(22) Filed: Nov. 12, 2010

(30) Foreign Application Priority Data
Sep. 29, 2010 (TW) 99132949

(51) Int. Cl. C23C 14/04; C23C 14/35

(52) U.S. Cl. 204/298.11

(57) ABSTRACT

An exemplary sputtering apparatus includes a deposition chamber, a anode support, a cathode support, and a shield device all received in the deposition chamber. The anode support supports workpieces. The cathode support is positioned opposite to the anode support and supports a target. The shield includes a rotary disk, a first arm, a second arm, a first shield plate and a second shield plate. The first and second arms are securely mounted to the rotary disk along the radial direction of the rotary disk. A radial extending direction of the first arm from the rotary disk is opposite to that of the second arm. The first shield plate is securely mounted to the first arm, and the second shield plate securely mounted to the second arm. The rotary disk rotates the first and second shield plates to selectively expose or shield the target.

### BACKGROUND

1. Technical Field

The present disclosure relates to sputtering apparatuses.

2. Description of Related Art

Sputtering deposition is a physical vapor deposition (PVD) method of depositing thin films by sputtering in a deposition chamber. In particular, plasma bombards a target, and the bombarded target material then deposits onto a workpiece such as a substrate or a wafer. However, the concentration of the bombarded target material may become nonuniform in the deposition chamber, which results a nonuniform film being coated on the workpiece.

Therefore, a sputtering apparatus which can overcome the limitations described is needed.

### BRIEF DESCRIPTION OF THE DRAWINGS

FIG. 1 is a functional block diagram of a sputtering apparatus including a first deposition chamber and a second deposition chamber, according to an exemplary embodiment.

FIG. 2 is a side sectional view of the first deposition chamber of FIG. 1, the first deposition chamber including a first shield device and a first target received therein, the first shield device shown in a first state.

FIG. 3 is an enlarged, abbreviated, top plan view of the first shield device and the first target of FIG. 2.

FIG. 4 is a side sectional view of the second deposition chamber of FIG. 1.

FIG. 5 is similar to FIG. 2, but shows the first shield device in a second state.

FIG. 6 is similar to FIG. 5, but shows the first shield device in a third state.

### DETAILED DESCRIPTION

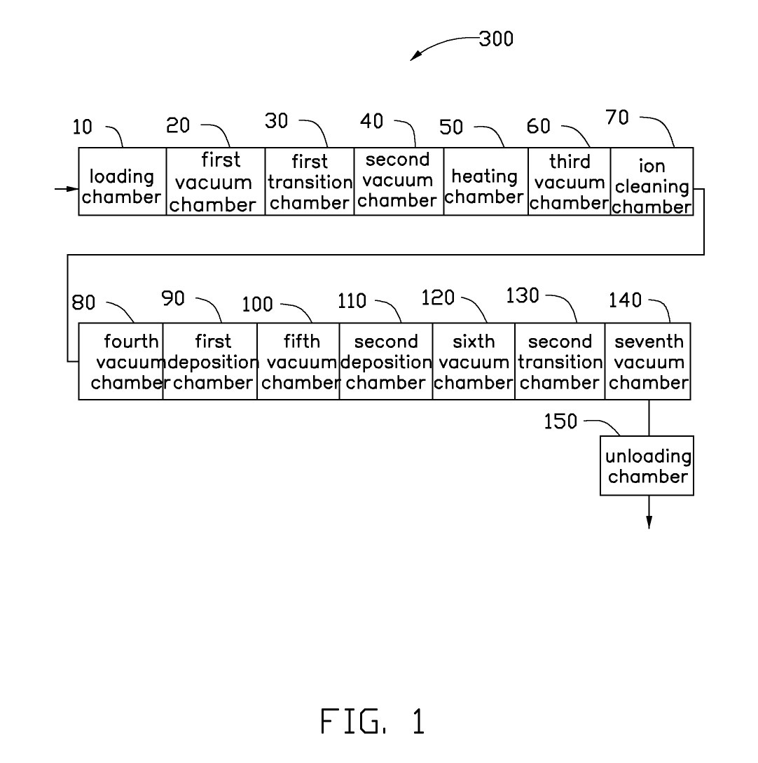

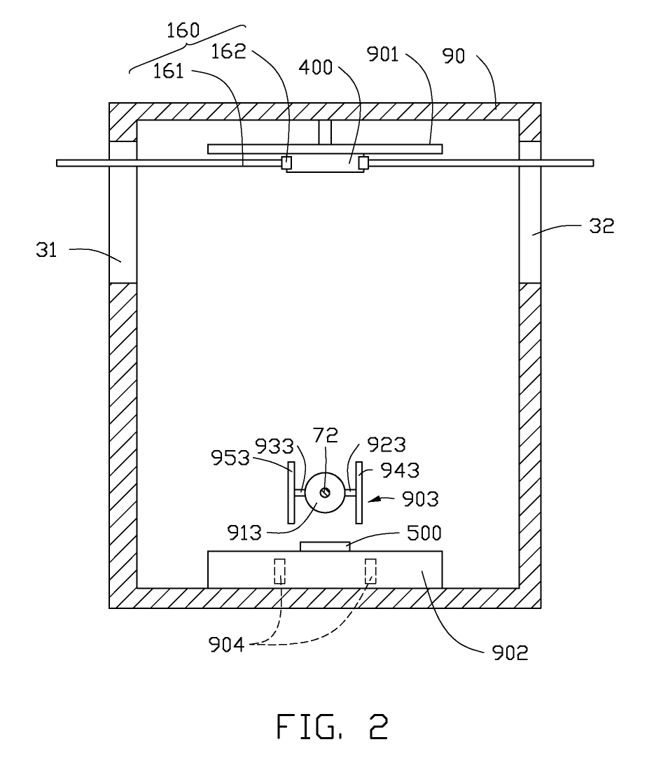

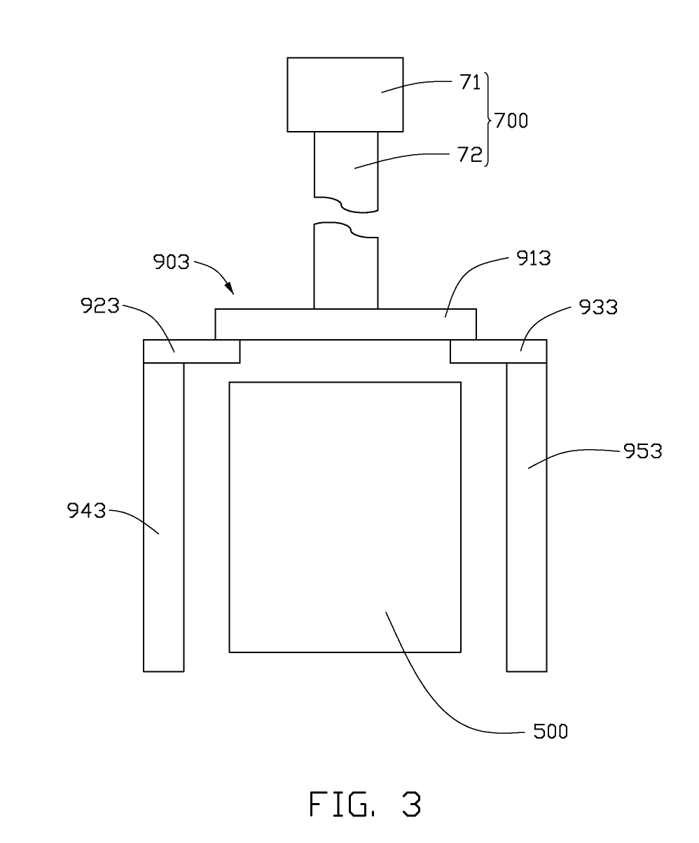

Referring to FIG. 1, a sputtering apparatus 300 according to an exemplary embodiment is shown. In the illustrated embodiment, the sputtering apparatus 300 is an in-line sputtering apparatus. Referring also to FIGS. 2 and 3, the sputtering apparatus 300 includes a loading chamber 10, a first vacuum chamber 20, a first transition chamber 30, a second vacuum chamber 40, a heating chamber 50, a third vacuum chamber 60, an ion cleaning chamber 70, a fourth vacuum chamber 80, a first deposition chamber 90, a fifth vacuum chamber 100, a second deposition chamber 110, a sixth vacuum chamber 120, a second transition chamber 130, a seventh vacuum chamber 140, an unloading chamber 150, a transporting device 160, and a motor 700.

The first vacuum chamber 20 connects the loading chamber 10 to the first transition chamber 30. The second vacuum chamber 40 connects the first transition chamber 30 to the heating chamber 50. The third vacuum chamber 60 connects the heating chamber 50 to the ion cleaning chamber 70. The fourth vacuum chamber 80 connects the ion cleaning chamber 70 to the first deposition chamber 90. The fifth vacuum chamber 100 connects the first deposition chamber 90 to the second deposition chamber 110. The sixth vacuum chamber 120 connects the second deposition chamber 110 to the second transition chamber 130. The seventh vacuum chamber 140 connects the second transition chamber 130 to the unloading chamber 150. A door (not shown) is arranged between each two neighboring chambers to selectively seal the chambers and open a passage between the two neighboring chambers.

The transporting device 160 includes a transporting belt 161, and a clamp 162 mounted to the transporting belt 161. The clamp 162 is configured for holding workpieces 400. The transporting device 160 is configured for moving the workpieces 400 through the chambers in the following order: the loading chamber 10, the first vacuum chamber 20, the first transition chamber 30, the second vacuum chamber 40, the heating chamber 50, the third vacuum chamber 60, the ion cleaning chamber 70, the fourth vacuum chamber 80, the first deposition chamber 90, the fifth vacuum chamber 100, the second deposition chamber 110, the sixth vacuum chamber 120, the second transition chamber 130, the seventh vacuum chamber 140, and the unloading chamber 150. Operators can collect coated workpieces 400 from the unloading chamber 150.

The first deposition chamber 90 and the second deposition chamber 110 each define a first opening 31 and a second opening 32 at opposite sides thereof. The movable doors can open and close the first opening 31 and the second opening 32. The workpiece 400 is introduced into the deposition chamber 90, 110 through the first opening 31 and moves out of the deposition chamber 90, 110 through the second opening 32.

The sputtering apparatus 300 further includes a first anode support 901, a first cathode support 902, a first shield device 903, and a first magnetron 904 all received in the first deposition chamber 90.

The first anode support 901 opposes the first cathode support 902 and is secured to an upper portion of the first deposition chamber 90. The first anode support 901 is configured for supporting (holding) the workpiece 400. The first cathode support 902 is secured to a bottom portion of the first deposition chamber 90, and is configured for supporting a first target 500.

The first shield device 903 is rotatably positioned between the first anode support 901 and the first cathode support 902. The first shield device 903 is nearer the first cathode support 902 than it is to the first anode support 901. The first shield device 903 is spaced from the first target 500 a predetermined distance. The first shield device 903 includes a rotary disk 913, a first arm 923, a second arm 933, a first shield plate 943, and a second shield plate 953.

The first arm 923 and the second arm 933 are securely mounted to a periphery of the rotary disk 913. Each of the first and second arms 923, 933 extends from the rotary disk 913 along a radial direction of the rotary disk 913. The extending direction of the first arm 923 from the rotary disk 913 is opposite to that of the second arm 933. That is, the first and second arms 923, 933 are aligned with each other. The first shield plate 943 is securely mounted to the first arm 923. The second shield plate 953 is securely mounted to the second arm 933. In this embodiment, the first shield plate 943 is perpendicular to the first arm 923, and the second shield plate 953 is perpendicular to the second arm 933. Thus the first shield plate 943 is parallel to the second shield plate 953. In alternative embodiments, the first shield plate 943 and the second shield plate 953 may be inclined slightly toward each other.

The rotary disk 913 rotates the first shield plate 943 and the second shield plate 953 to expose or shield the first target 500. Specifically, referring to FIG. 2, the first shield plate 943 and the second shield plate 953 are substantially perpendicular to the first target 500 (i.e., the first cathode support 902). Under this condition, areas of orthographic projections of the first and second shield plates 943, 953 on the first target 500 are small, and the first target 500 can be considered to be exposed by the first and second shield plates 943, 953. Therefore, plasma can easily bombard the first target 500 when the deposition is in process, and the concentration of bombarded target material dislodged from the first target 500 is high.

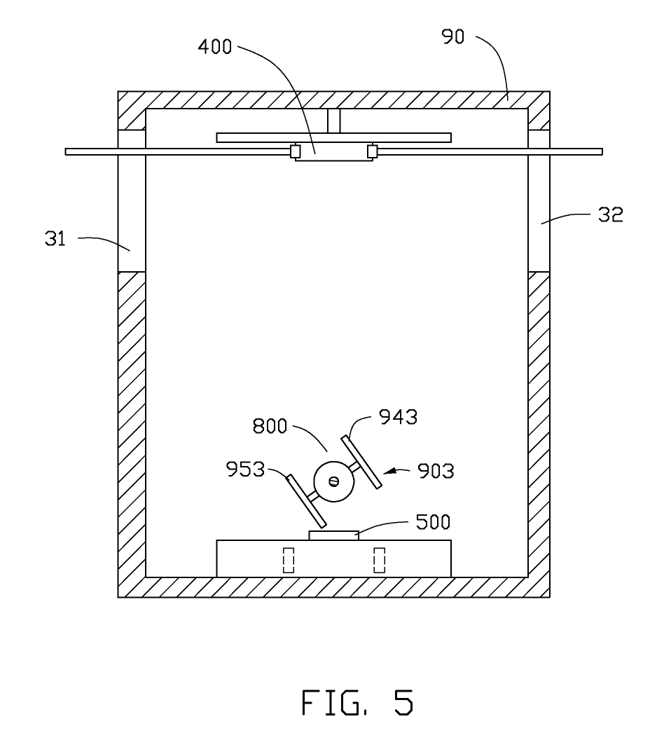

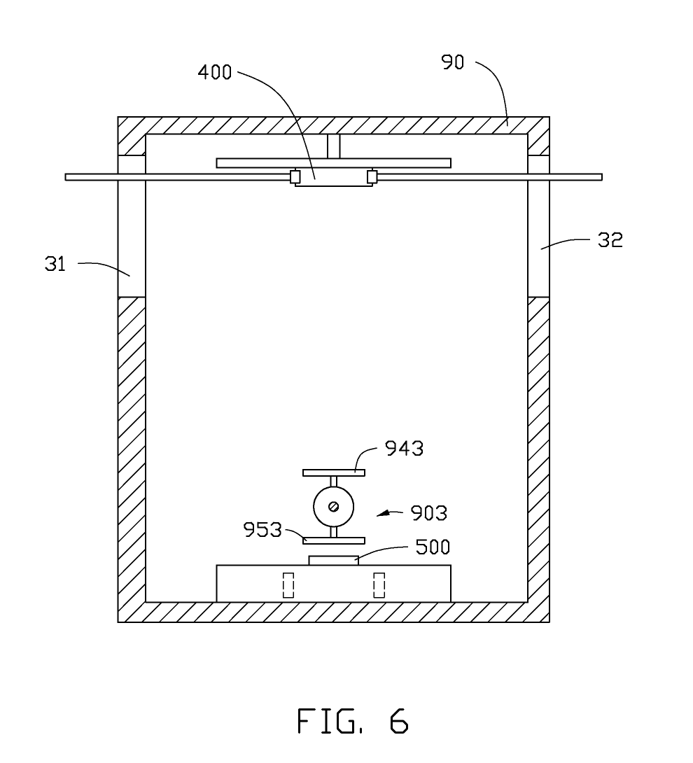

Referring also to FIGS. 5 and 6, with rotation of the rotary disk 913, areas of orthographic projections of the first and second shield plates 943, 953 on the first target 500 can be increased until the first and second shield plates 943, 953 are substantially parallel to the first target 500. Under this condition, the first target 500 can be considered to be shielded by the first and second shield plates 943, 953. Therefore, plasma does not easily bombard the first target 500 when the deposition is in process, and the concentration of the bombarded target material dislodged from the first target 500 is reduced.

The first magnetron 904 is embedded in the first cathode support 902. The first magnetron 904 is configured for trapping electrons close to the surface of the first target 500. The electrons follow helical paths around the magnetic field lines undergoing more ionizing collisions with reaction gas. Therefore, more ionized reaction gas bombards the first target 500, resulting in more bombarded target material escaping from the first target 500. This increases a deposition rate of the sputtering apparatus 300.

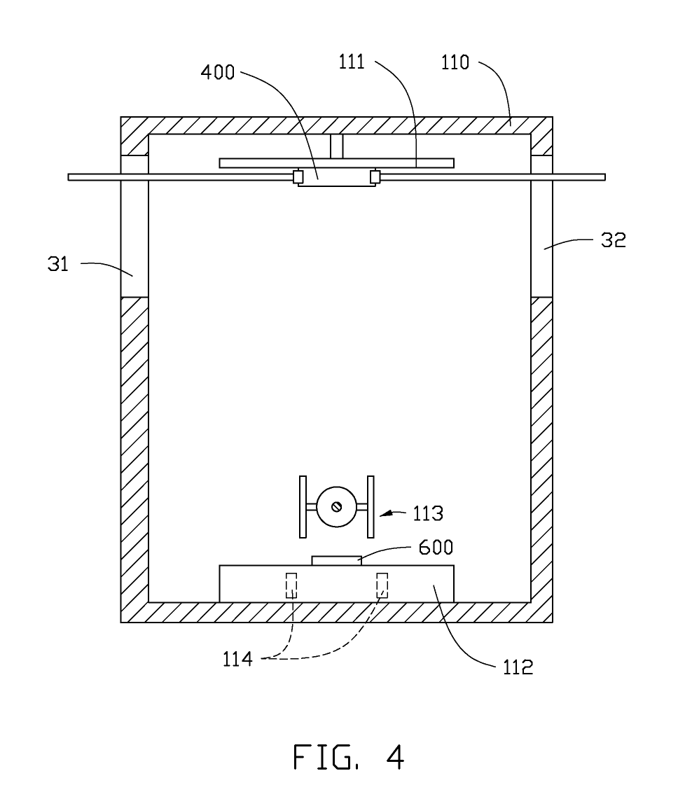

Referring to FIG. 4, the sputtering apparatus 300 further includes a second anode support 111, a second cathode support 112, a second shield device 113, and a second magnetron 114 all received in the second deposition chamber 110. The second cathode support 112 is configured for supporting a second target 600. Material of the second target 600 is different from that of the first target 500. Therefore, the sputtering apparatus coats the workpiece 400 with two layers of film.

The configuration of the second shield device 113 is substantially the same as that of the first shield device 903. Configurations of the second anode support 111, the second cathode support 113, and the second magnetron 114 are substantially the same as those of the first anode support 901, the first cathode support 902, and the first magnetron 904 respectively.

Referring particularly to FIG. 3, the motor 700 is configured for rotating the first shield device 903. The motor 700 includes a stator 71, and a rotor 72 connected to the stator 71. The stator 71 is positioned outside the first deposition chamber 90. The rotor 72 rotatably extends through a sidewall of the first deposition chamber 90 and is secured to the rotary disk 913. In alternative embodiments, the motor 700 can be received in the first deposition chamber 90. It is to be understood that, although not shown in drawings, another motor is used for rotating the second shield device 113 in the second deposition chamber 110. This other motor is substantially the same as the motor 700.

When in use, the workpiece 400 is loaded on the transporting device 160 in the loading chamber 10, and is transported by the transporting device 160 to the first vacuum chamber 20, the first transition chamber 30, the second vacuum chamber 40, the heating chamber 50, the third vacuum chamber 60, the ion cleaning chamber 70, and the fourth vacuum chamber 80 in that order, and thence to the first deposition chamber 90.

In the first deposition chamber 90, the concentration of the bombarded target material may be or become nonuniform. For example, the concentration of the bombarded target material at the left side of the first deposition chamber 90 may be greater than that at the right side of the first deposition chamber 90. In these circumstances, the motor 700 is activated to rotate the first shield device 903 (see FIG. 2) counterclockwise. The second shield plate 953 gradually shields more and more of a left portion of the first target 500 as the first shield device 903 rotates (see FIG. 5). Therefore, plasma does not easily bombard the left portion of the first target 500, and the concentration of the bombarded target material at the left side of the first deposition chamber 90 is apt to reduce. Meanwhile, a guide passage 800 formed between the first shield plate 943 and the second shield plate 953 is inclined relative to the first target 500. The guide passage 800 guides the plasma in the first deposition chamber 90 towards a right portion of the first target 500. Therefore more target material at the right portion of the first target 500 is bombarded by the guided plasma, and the concentration of the bombarded target material at the right side of the first deposition chamber 90 is increased. Thus, the first shield plate 943 is able to reach an equilibrium position at which the concentration of the bombarded target material in the first deposition chamber 90 tends to be substantially uniform, and the workpiece 400 can be coated uniformly. It is to be understood that commercially available concentration sensors may be used to sense the concentration of the bombarded target material in the first deposition chamber 90, and output the results to a visual terminal such as a display.

When coating of a first layer in the first deposition chamber 90 has finished, the workpiece 400 is transported to the second deposition chamber 110 to implement a second layer coating. Finally, the coated workpiece 400 is deposited in the unloading chamber 150 where it can be collected by an operator.

In alternative embodiments, the number of deposition chambers may be different, depending upon the number of layers that need to be coated on the workpiece 400. Each layer is coated in a corresponding deposition chamber.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A sputtering apparatus, comprising:
a first deposition chamber;
a first anode support received in the first deposition chamber and configured for supporting a workpiece;
a first cathode support received in the first deposition chamber and positioned opposite to the first anode support, the first cathode support configured for supporting a first target; and
a first shield device rotatably positioned between the first anode support and the first cathode support, the first shield device comprising a rotary disk, a first arm, a second arm, a first shield plate and a second shield plate, the first arm and the second arm securely mounted to opposite sides of the rotary disk, a radial extending direction of the first arm from the rotary disk being opposite to that of the second arm, the first shield plate securely mounted to the first arm, and the second shield plate securely mounted to the second arm, the rotary disk configured for rotating the first shield plate and the second shield plate to selectively expose or shield the first target.

2. The sputtering apparatus of claim 1, further comprising a motor configured for rotating the rotary disk.

3. The sputtering apparatus of claim 1, further comprising a loading chamber, a first vacuum chamber, a first transition chamber, a second vacuum chamber, a heating chamber, a third vacuum chamber, an ion cleaning chamber, a fourth vacuum chamber, a fifth vacuum chamber, a second deposition chamber, a sixth vacuum chamber, a second transition chamber, a seventh vacuum chamber, and an unloading chamber, the first vacuum chamber connecting the loading chamber and the first transition chamber, the second vacuum chamber connecting the first transition chamber and the heating chamber, the third vacuum chamber connecting the heating chamber and the ion cleaning chamber, the fourth vacuum chamber connecting the ion cleaning chamber and the first deposition chamber, the fifth vacuum chamber connecting the first deposition chamber and the second deposition chamber, the sixth vacuum chamber connecting the second deposition chamber and the second transition chamber, and the seventh vacuum chamber connecting the second transition chamber and the unloading chamber.

4. The sputtering apparatus of claim 3, further comprising a transporting device, the transporting device configured for moving the workpiece from the loading chamber to the first vacuum chamber, the first transition chamber, the second vacuum chamber, the heating chamber, the third vacuum chamber, the ion cleaning chamber, the fourth vacuum chamber, the first deposition chamber, the fifth vacuum chamber, the second deposition chamber, the sixth vacuum chamber, the second transition chamber, the seventh vacuum chamber, and the unloading chamber in that order.

5. The sputtering apparatus of claim 3, further comprising a second anode support, a second cathode support, and a second shield device all received in the second deposition chamber, the second anode support positioned opposite to the second cathode support, the second anode support configured for supporting the workpiece, the second cathode support configured for supporting a second target, the configuration of the second shield device being substantially the same as that of the first shield device, a rotary disk of the second shield device configured for rotating first and second shield plates of the second shield device to expose or shield the second target, and material of the second target being different from that of the first target.

6. The sputtering apparatus of claim 4, wherein the transporting device comprises a transporting belt and a clamp mounted to the transporting belt, the clamp configured for holding the workpiece.

7. The sputtering apparatus of claim 1, further comprising a magnetron embedded in the first cathode support.

8. The sputtering apparatus of claim 1, wherein the first shield plate and the second shield plate are substantially parallel to each other.

9. The sputtering apparatus of claim 8, wherein when the first shield plate and the second shield plate are inclined relative to the first target, the first shield device at least partly shields a side portion of the first target, the first and second shield plates cooperatively define an inclined guide passage therebetween, and one end of the guide passage is exposed toward another side portion of the first target.

10. The sputtering apparatus of claim 1, wherein the first shield plate and the second shield plate are inclined toward each other.

11. The sputtering apparatus of claim 1, wherein the first shield device is nearer the first cathode support than the first anode support.

12. A sputtering apparatus, comprising:
a deposition chamber;
a anode support received in the deposition chamber and configured for supporting a workpiece;
a cathode support received in the deposition chamber and positioned opposite to the anode support, the cathode support configured for holding a target; and
a shield device rotatably positioned between the anode support and the cathode support, the shield device comprising a rotary disk, and a first shield plate and a second shield plate mounted at opposite sides of the rotary disk, the rotary disk configured for selectively rotating the first and second shield plates to any of desired positions ranging from a first position in which the shield device maximally exposes the target and a second position in which the shield device maximally shields the target.

13. The sputtering apparatus of claim 12, wherein the first shield plate and the second shield plate are substantially parallel to each other, and at least one of the desired positions is a position in which the first and second shield plates are inclined relative to the target.

14. The sputtering apparatus of claim 13, wherein in the at least one of the desired positions, the shield device at least partly shields a side portion of the target, the first and second shield plates cooperatively define an inclined guide passage therebetween, and one end of the guide passage is exposed toward another side portion of the target.

15. The sputtering apparatus of claim 14, wherein in the at least one of the desired positions, the at least partial shielding of the side portion of the target provides reduced bombarding of the side portion of the target by plasma, and the one end of the guide passage being exposed toward the other side portion of the target provides increased bombarding of the other side portion of the target by guided plasma.

16. The sputtering apparatus of claim 15, wherein in the first position, the concentration of bombarded target material from the target in the deposition chamber is nonuniform, and in the at least one of the desired positions, the reduced bombarding of the side portion of the target by plasma and the increased bombarding of the other side portion of the target by guided plasma cooperatively provide an equilibrium such that the concentration of bombarded target material from the target in the deposition chamber is substantially uniform.
